(19) United States
(12) Patent Application Publication
(10) Pub. No.: US 2025/0393139 A1
(43) Pub. Date: Dec. 25, 2025

(54) DOOR INTERLOCK FOR TELECOMMUNICATION CABINETS

(71) Applicant: VERTIV CORPORATION, Westerville, OH (US)

(72) Inventors: Matthew A. Podemski, Auburn, AL (US); Michael D. Blom, JR., Opelika, AL (US)

(21) Appl. No.: 19/201,328

(22) Filed: May 7, 2025

Related U.S. Application Data
(60) Provisional application No. 63/662,615, filed on Jun. 21, 2024.

(51) Int. Cl. H05K 5/02; H05K 7/14; H05K 7/18

(52) U.S. Cl. CPC H05K 5/0208; H05K 7/1488; H05K 7/186

(57) ABSTRACT

A cabinet may include a cabinet frame, a front door coupled to a front side of the cabinet frame, and a rear door coupled to a rear side of the cabinet frame comprising a rear cam mechanically disposed on an internal side of a rear door. The rear cam is configured to couple the rear door to the rear side of the cabinet frame in a lock position. A cabinet may include a rod positioned orthogonal to the front door and to the rear door, wherein a closed configuration of the front door contacts a front end of the rod and biases a rear end of the rod toward the rear door from an unblock position to a block position, wherein the biasing of the rod from the unblock position to the block position prevents a rotation of the rear cam from the lock position to the unlock position.

### CROSS-REFERENCE TO RELATED APPLICATIONS

The present application claims priority to U.S. Provisional Patent Application No. 63/662,615, filed Jun. 21, 2024, which is incorporated herein by reference in its entirety.

### TECHNICAL FIELD

The present disclosure relates to cabinets and more particularly to locking mechanisms of server cabinets.

### BACKGROUND

Electronic equipment, such as servers in data centers, are often stored in cabinets. These cabinets provide protection and security for the electronic equipment while providing technicians access to the electronic equipment through one or more doors. For example, the cabinet may include a front door and rear door, allowing the technician access to the front side and back side of the servers.

Because the rear cabinet door is often associated with cooling systems and/or other functionality of the cabinet, it is important that the rear cabinet door is closed and latched when the cabinet is not being attended to by a technician. For example, if the rear door is latched and slightly ajar, the technician may not notice, and cooling fans that are intended to circulate air through the cabinet may instead leak air through the space provided by the slightly ajar rear door. In another example, an unlatched and thereby unlocked rear door could increase the risk of vandalism, theft, or damage from weather. Therefore, there is a need for a cabinet that ensures that the rear door is closed and/or sealed from the outside environment, yet still allows for easy access to both doors by a technician.

### SUMMARY

In some aspects, the techniques described herein relate to a cabinet including: a cabinet frame; a front door coupled to a front side of the cabinet frame: a rear door coupled to a rear side of the cabinet frame including a rear cam mechanically disposed on an internal side of a rear door, wherein the rear cam is configured to rotate between a lock position and unlock position, wherein the rear cam couples the rear door to the rear side of the cabinet frame, in the lock position; a rod positioned orthogonal to the front door and to the rear door, wherein a closed configuration of the front door contacts a front end of the rod and biases a rear end of the rod toward the rear door from an unblock position to a block position, wherein the biasing of the rod from the unblock position to the block position prevents a rotation of the rear cam from the lock position to the unlock position; and a first biasing element configured to bias the rod from the block position to the unblock position upon an opening of the front door, wherein biasing the rod from the block position to the unblock position allows the rear cam to move from the lock position to the unlock position.

In some aspects, the techniques described herein relate to a system including: a cabinet including: a cabinet frame; a front door coupled to a front side of the cabinet frame including: a rear door coupled to a rear side of the cabinet frame including: a rear cam base accessible from an external side of the rear door; and a rear cam disposed on an internal side of the rear door and mechanically coupled to the rear cam base, wherein the rear cam is configured to rotate between a lock position and unlock position, wherein the rear cam couples the rear door to the rear side of the cabinet frame in the lock position; a rod mechanically coupled to at least one of the cabinet frame or a cabinet panel and positioned orthogonal to the front door and to the rear door, wherein a closed configuration of the front door contacts a front end of the rod and biases a rear end of the rod toward the rear door from an unblock position to a block position, wherein the biasing of the rod from the unblock position to the block position prevents a rotation of the rear cam from the lock position to the unlock position; a first biasing element configured to bias the rod from the block position to the unblock position upon an opening of the front door, wherein biasing the rod from the block position to the unblock position allows the rear cam to move from the lock position to the unlock position; and a bias bracket including: a block; and a second biasing element coupled to the block, the second biasing element configured to bias the block against the rear cam, whereupon a movement of the rear cam from the lock to the unlock position causes the block to translate from a non-obstruct position to an obstruct position via the second biasing element, whereupon the translation of the block from the non-obstruct position to the obstruct position causes the rod to be blocked from biasing from the unblock position to the block position, wherein when the rod is the block position a front end of the rod extends outward to an extended position, wherein a resulting extension of the front end of the rod in the extended position blocks the front door and prevents the front door from fully closing.

In some aspects, the techniques described herein relate to a method for operating a rear door and a front door of a cabinet, when the rear door and the front door are each initially closed, the method including: opening the rear door, wherein opening the rear door includes: opening the front door, wherein opening the front door causes a rod to move from a block position to an unblock position; rotating a rear cam from a lock position to an unlock position, wherein rotating the rear cam from the lock position to the unlock position causes a block to move from a non-obstruct position to an obstruct position, wherein causing the block to move from the non-obstruct position to the obstruct position prevents the rod from moving to the block position and prevents the front door from fully closing; and pulling on the rear door to an open position.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE FIGURES

The detailed description is described with reference to the accompanying figures. The use of the same reference numbers in different instances in the description and the figures may indicate similar or identical items. Various embodiments or examples (“examples”) of the present disclosure are disclosed in the following detailed description and the accompanying drawings. The drawings are not necessarily to scale. In general, operations of disclosed processes may be performed in an arbitrary order, unless otherwise provided in the claims.

FIGS. 1A-1B illustrate perspective views of a system that includes a cabinet, in accordance with one or more embodiments of the disclosure.

FIG. 2 illustrates a close-up view of the rear door and rear door frame, in accordance with one or more embodiments of the disclosure.

FIG. 3 illustrates a close-up side view of the top panel of the cabinet, in accordance with one or more embodiments of the disclosure.

FIG. 4A-4B illustrate perspective inside views of the cabinet, in accordance with one or more embodiments of the disclosure.

FIG. 4C illustrates a perspective inside view of the cabinet with the rear end of the rod positioned in an unblock position and the rear cam rotated to an unlock position, in accordance with one or more embodiments of the disclosure.

FIG. 5 illustrates a perspective view of a bias bracket, in accordance with one or more embodiments of the disclosure.

FIGS. 6A-6B illustrate perspective inside views of the cabinet with the block positioned in a non-obstruct position and an obstruct position, respectively.

FIG. 7 illustrates a perspective external view of a top portion of the cabinet with the front door open, in accordance with one or more embodiments of the disclosure.

FIG. 8 illustrates a process flow diagram depicting a method for operating the rear door and the front door of the cabinet when the front door and the rear door are initially closed, in accordance with one or more embodiments of the disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present), and B is false (or not present), A is false (or not present), and B is true (or present), and both A and B are true (or present).

In addition, the use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “one embodiment” or “embodiments” means that a particular element, feature, structure, or characteristic described in connection with the embodiment is included in at least one embodiment disclosed herein. The appearances of the phrase “in embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

Reference will now be made in detail to the subject matter disclosed, which is illustrated in the accompanying drawings.

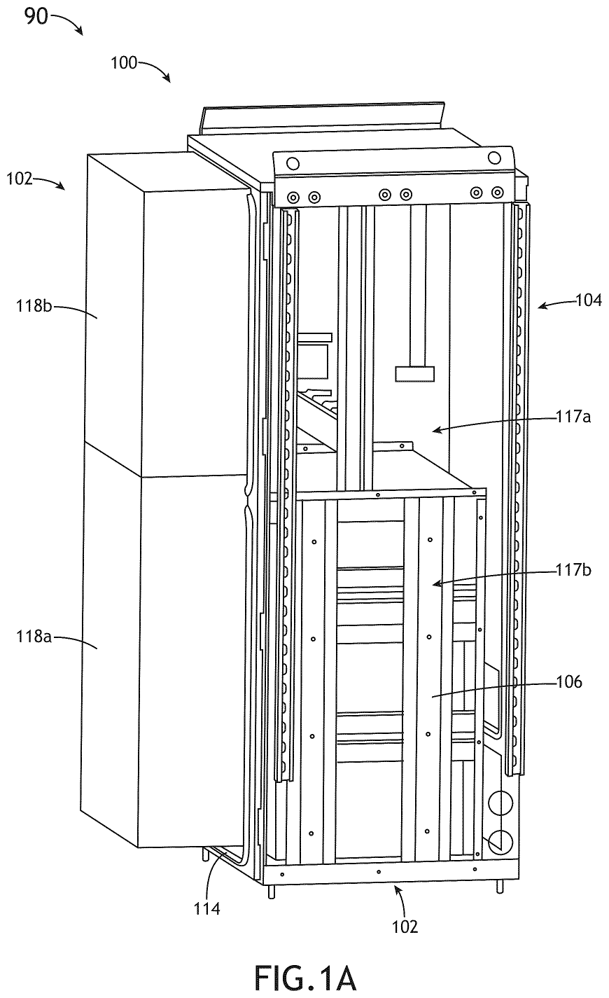

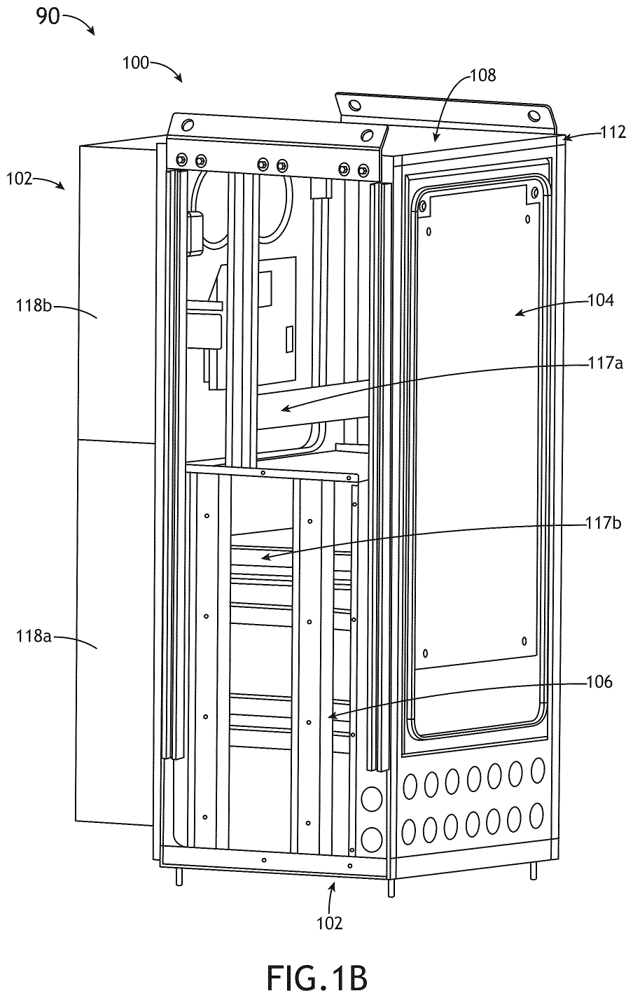

FIGS. 1 through 8 illustrate a cabinet for storing electronic equipment, such as telecommunication batteries and power equipment; and/or related servers, in accordance with one or more embodiments of the server. The cabinet includes a front door, a rear door, and a mechanism that 1) does not allow the rear door to be unlatched and opened unless the front door has been opened, and 2) does not allow the front door to be closed unless the rear door has been closed and latched. The mechanism ensures that both the front door and back door are closed and sealed.

The embodiments of the present disclosure are particularly advantageous, as the mechanism reduces the incidence of the rear door accidentally being left unlatched, as a technician attempting to close the front door with the rear door open would notice that the front door is not able to close, and upon investigation would notice the rear door not being closed as well. Furthermore, because front doors often face hallways, the open front door is more likely to be noticed by the technician than an open rear door that faces a wall. By reducing the incidence of an open rear door, the cabinet provides better security for the contents of the cabinet that are configured for operating with the rear door closed.

FIGS. 1A-1B illustrate perspective views of a system 90 that includes a cabinet 100, in accordance with one or more embodiments of the disclosure. The cabinet 100 may be configured to store any type of goods. For example, the cabinet 100 may be configured to store electronic equipment, such as batteries, power equipment, and/or related servers. For instance, the cabinet 100 may be configured to store batteries and/or related power equipment, with the cabinet 100 serving as an outside plant (OSP) enclosure. The cabinet 100 includes a front door 102 coupled to a front side of the cabinet 100 frame, a rear door 104 coupled to a rear side of the cabinet 100, one or more side panels 106 (e.g., which may or may not include doors), a top panel 108, and a bottom panel 110, held together by a cabinet frame 112. The cabinet 100 may also include a front door frame 114 and rear door frame 116 that receive the front door 102 and the rear door 104, respectively. The cabinet 100 may also include one or more cooling systems 118a-b, such as an air-cooling system (e.g., containing one or more fans) or a liquid cooling system. The cabinet 100 can also include one or more storage compartments 117a-b and/or related shelves for carrying any batteries and/or related power equipment.

The designation of one door as a front door 102, and another door as a rear door 104 is for illustrative purposes only. For example, the cabinet door designation could be reversed, with the closing mechanism 1) not allowing the front door to be unlatched and opened unless the rear door has been opened, and 2) not allowing the rear door to be closed unless the front door has been closed and latched. Therefore, the above description should not be interpreted as a limitation of the present disclosure, but merely an illustration.

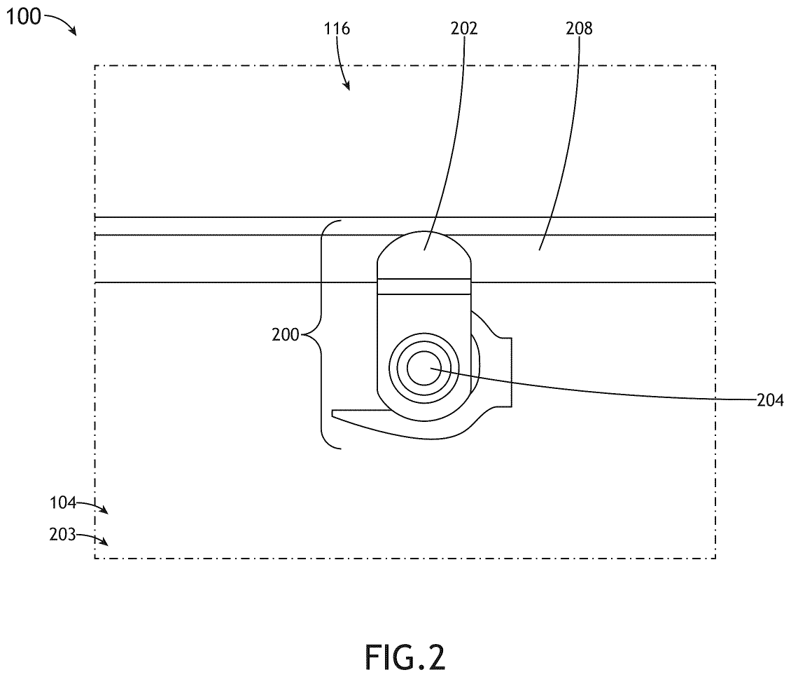

FIG. 2 illustrates a close-up view of the rear door 104 and rear door frame 116, in accordance with one or more embodiments of the disclosure. In embodiments, the cabinet 100 includes one or more rear cam locks 200 configured to secure the rear door 104 to the rear door frame 116 in a closed position. The one or more rear cam locks 200 include a rear cam 202 mechanically and rotationally coupled to, and/or disposed on, an internal side 203 of the rear door 104 via a rear cam base 204. The rear cam base 204 is accessible from an external side of the rear door 104, such as with a key or turnbutton. The rear cam 202 is configured to rotate from an unlocked position to a locked position (e.g., as shown in FIG. 2). In the locked position, the rear cam 202 latches the rear door 104 to the rear door frame 116 and/or a rib 208 on the rear door frame 116. The front door 102 may also include one or more locking mechanisms, such as a front cam latch that includes a front cam and front cam base.

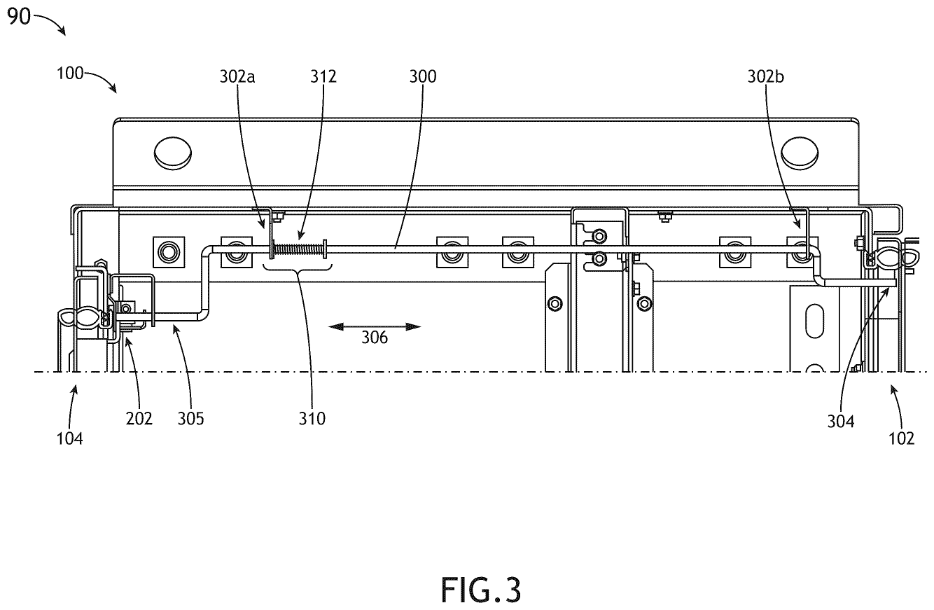

FIG. 3 illustrates a close-up side view of the top panel 108 of the cabinet 100, in accordance with one or more embodiments of the disclosure. In embodiments, the cabinet includes a rod 300 mechanically coupled to the cabinet frame 112 or a cabinet panel (e.g., top panel 108 or one or more side panels 106) and positioned orthogonal to the front door 102 and to the rear door 104 (e.g., the rod 300 extending to approximately both the front door 102 and the rear door 104). The rod 300 may be mechanically coupled to one of the cabinet frame 112, top panel 108, bottom panel 110, or one or more side panels. For example, the rod may be mechanically coupled to the top panel 108 via one or more loops 202a-b that permit the rod 300 to slide or translate between the front door 102 and the rear door 104. For example, closing the front door 102 (e.g., the door being placed in a closed configuration) may cause the front door 102 to contact and bias a front end 304 of the rod 300, causing a translation 306 of the rod 300, and a rear end 305 of the rod 300 toward the rear door 104 to a block position that prevents the rear cam 202 from rotating. In another example, opening the front door 102 may cause the rod to translate toward, and partially extend out of, the opening of the front door, as described herein.

In embodiments, the cabinet 100 includes a first biasing element 310 that is configured to bias the rod 300 toward the front door 102. The first biasing element 310 may include any type of biasing mechanism including, but not limited to, a spring 312. For instance, the first biasing element 310 may include a compression spring that is mechanically coupled to one of the loops 302a and to the rod 300. In particular, the first biasing element 310 may configured so that when the front door 102 is moved to a closing position, and the rod 300 is translated toward the rear door 104 by the front door 102 biasing the rod 300, the compression spring is compressed. When the front door 102 is opened, the compressed spring 312 releases, biasing the rod 300 toward the front door 102.

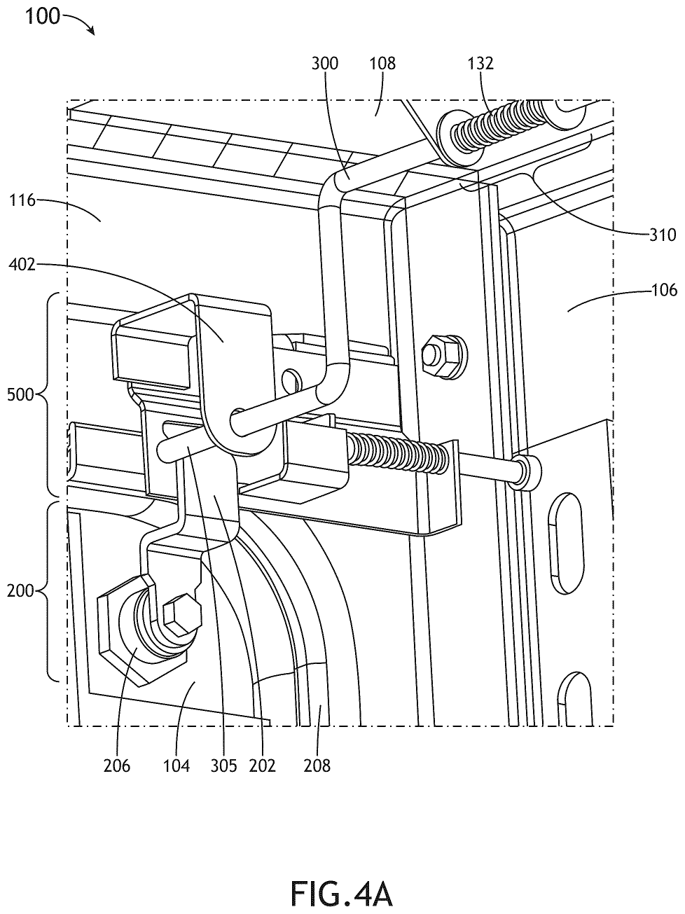

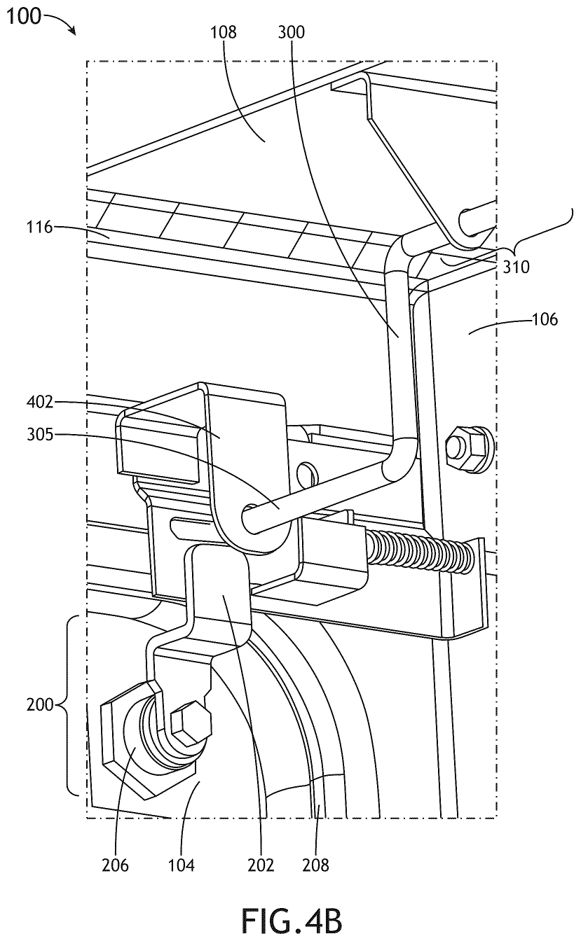

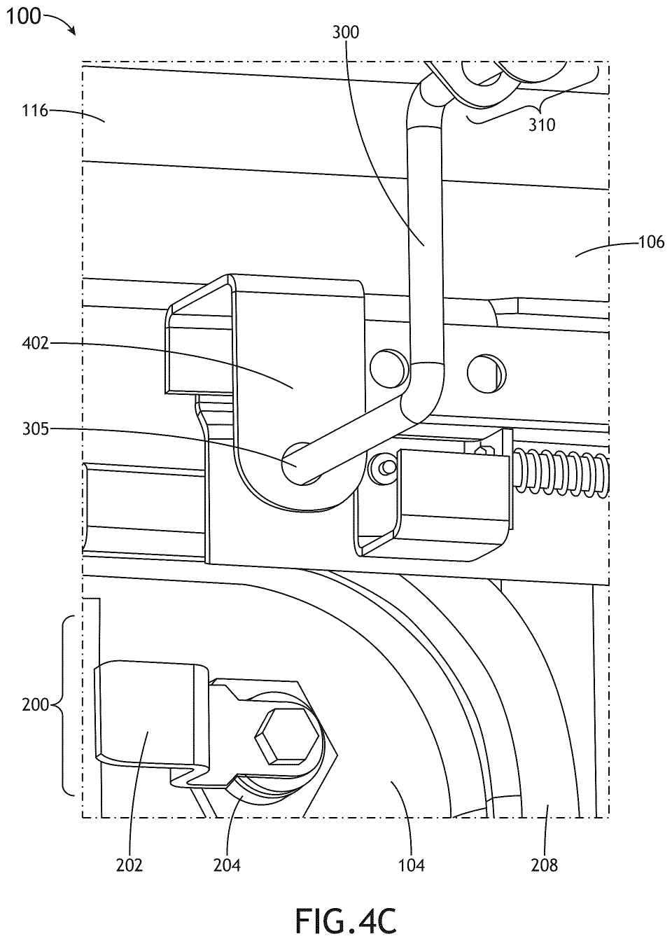

FIG. 4A illustrates a perspective inside view of the cabinet 100, in accordance with one or more embodiments of the disclosure. The figure shows the rear cam lock 200 in a lock position, securing the rear door 104 to the rear door frame 116. The rod 300 is shown in the block position (e.g., where a rear end 305 of the rod 300 prevents the rear cam 202 from rotating to the unlock position).

In embodiments, when the rod 300 is biased toward the rear door 104 (e.g., in the block position), the rear cam 202 is prevented from moving from the lock position to an unlock position. In the unlock position, the rear cam 202 no longer secures the rear door 104 to the rear door frame 116, allowing the rear door 104 to be pulled open. The cabinet 100 further includes a rod guide 402 that guides the rod 300 to the block position when the rod 300 is biased toward the rear door 104. The rod guide 402 may also prevent the rear cam 202 from moving the rod 300. In order to move the rear cam 202 from the lock position to the unlock position, the rod 300 can be first moved from the block position (e.g., as shown in FIG. 4A) to the unblock position, as shown in FIG. 4B, in accordance with one or more embodiments of the disclosure. For example, when the front door 102 is opened, the first biasing element 310 causes the rod 300 to translate away from the rear door 104 to the unblock position, allowing the rear cam 202 to rotate to the unlock position (e.g., via a key or turnbutton on the external side of the rear door 104).

FIG. 4C illustrates a perspective inside view of the cabinet 100 with the rear end 305 of the rod 300 positioned in an unblock position and the rear cam 202 rotated to an unlock position, in accordance with one or more embodiments of the disclosure. Once all rear cams 202 are in the unlock position, the rear door 104 may be pulled open. Also, as the rear cams are rotated to the unlock position, biasing mechanisms are able to prevent the rod 300 from returning to the block position, as described below.

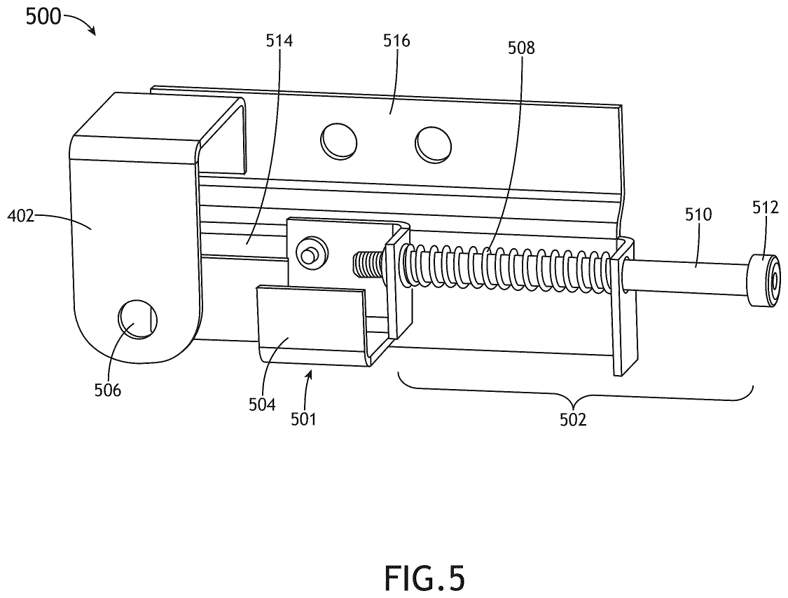

FIG. 5 illustrates a perspective view of a bias bracket 500, in accordance with one or more embodiments of the disclosure. In embodiments, the cabinet 100 includes a bias bracket 500 that is configured to prevent the rear end 305 of the rod 300 from moving to the block position after the rear cam 202 has been rotated from the lock position toward the unlock position. Preventing the rear end 305 of the rod 300 from moving back to the block position also simultaneously results in the front end 304 of the rod 300 remaining in an extended position. In the extended position, the front end 304 of the rod 300 can prevent the front door 102 from fully closing.

In embodiments, the bias bracket 500 includes a block 501 and a second biasing element 502 that is configured to bias the block 501 from a non-obstruct position (e.g., as shown in FIG. 5) to an obstruct position. In the obstruct position thereof, a face 504 of the block 501 is configured to block (e.g., obstruct) an aperture 506 of the rod guide 402, thereby preventing the rod 300 from reentering the rod guide and positioning the rear end 305 of the rod 300 in the block position. The second biasing element 502 may include any type of biasing device including, but not limited to, a spring 508. For example, the second biasing element 502 may be configured as a plunger having a stem 510 and a compression spring 508, with a head 512 of the stem 510 attached to one of the one or more side panels 106 so that the spring 508 is configured to be compressed when the block 501 is positioned in a non-obstruct position. The compressed spring 508 then is configured to bias the block 501 against the rear cam 202. The bias bracket 500 may include a track 514 that is configured to guide the movement of the block 501 from the non-obstruct position to the obstruct position. The bias bracket may be secured to the rear door frame 116, the top panel 108, and/or the one or more side panels 106 via a bracket element 516.

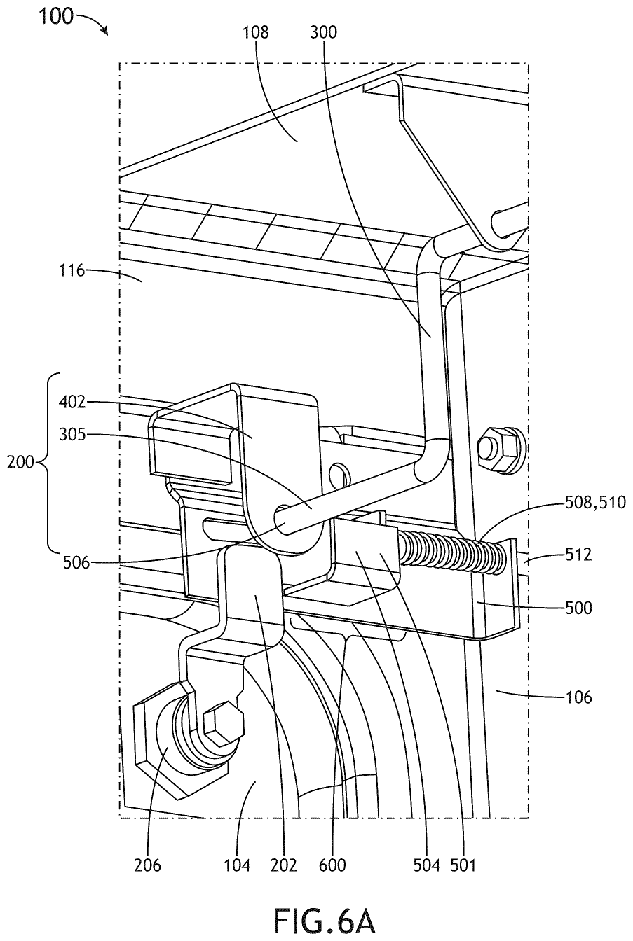

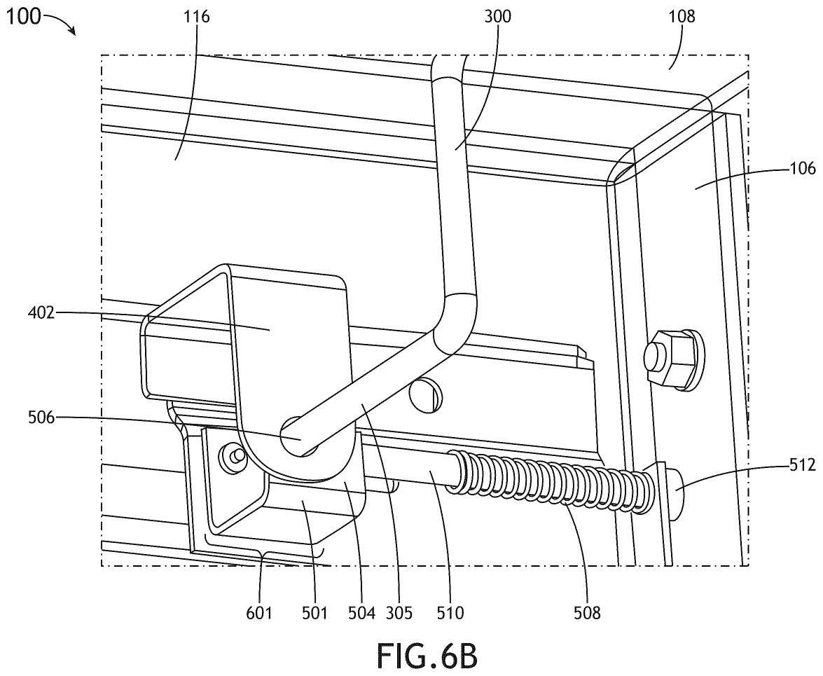

FIGS. 6A-6B illustrate perspective inside views of the cabinet 100 with the block 501 positioned in a non-obstruct position 600 and an obstruct position 601, respectively. For example, when the front door 102 is opened and the rod 300 has been biased to the unblock position, the rod 300 no longer blocks the rear cam 202, as shown in FIG. 6A. Upon rotating the rear cam 202 from the lock position to the unlock position, the block 501, biased by the stem 510 and spring 508 of the second biasing element 502, is moved to the obstruct position 601, with the face 504 of the block 501 obstructing the aperture 506 of the rod guide 402, preventing the rod 300 from moving from the unblock position to the block position.

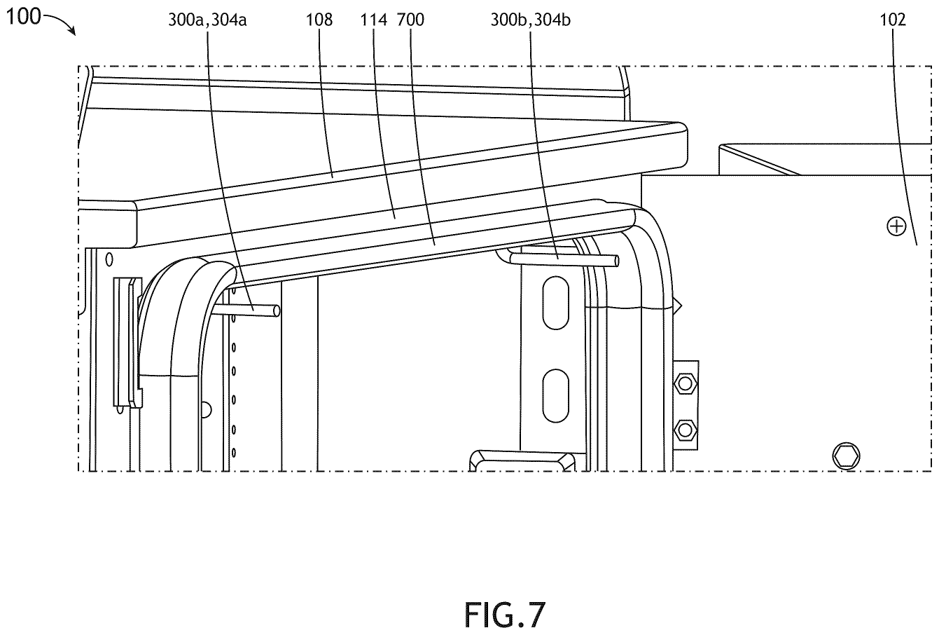

FIG. 7 illustrates a perspective external view of a top portion of the cabinet 100 with the front door open, in accordance with one or more embodiments of the disclosure. The cabinet 100 is shown with the front ends 304a-b of two rods 300a-b that extend outward from the interior of the cabinet 100 (e.g., extending beyond an interior boundary established by the front door frame 114 and/or a front door frame rib 700). For example, the front ends 304a-b of two rods 300a-b may extend past the front door frame 114 or the front door frame rib 700 of the cabinet when the two rods 300a-b are in their extended position. The front ends 304a-b of the rods 300a-b are configured to translate to the extended position when the front door 102 is opened via an action of their respective first biasing element 310 that bias the rods 300a-b to the extended position. To close the front door 102 (e.g., while the rear door 104 is closed and latched), the front door 102 is pushed closed with enough force that can overcome the force of each respective first biasing element 310. In embodiments where two or more rods 300a-b are implemented, the rods are similarly constructed and are configured to operate in a similar manner as disclosed herein.

In embodiments, the front ends 304a-b of the rods 300a-b prevent the front door 102 from closing to a closed position when the rods 300a-b are blocked from biasing from the unblock position to the block position. For example, after the front door 102 is opened, and the front ends 304a-b of rods 300a-b are biased by the first biasing element 310 into an extended position that extends outward of the front door doorway, the rotation of the rear cams 202 from the locked to unlocked position causes the second biasing element 502 to move the block 501 into the obstruct position 601, preventing the rods 300a-b from reversing from the extended position. Because the rods 300a-b cannot reverse from the extended position, the front door 102 cannot close as the front ends 304a-b of rods 300a-b are locked or frozen in the extended position, and remain unable to close until the rear door 104 is closed, and the rear cams 202 are rotated from the unlock position to the lock position. Such rotation biases and/or rotates the block 501 from the obstruct position 601 to non-obstruct position 600, which allows the rear ends 305 of the rods 300a-b to both move to the block position via the rod guide 402 and the front ends 304a-b of the rods 300a-b simultaneously to retreat from the extended position.

When the rods 300a-b are positioned in the extended position, the front ends 304a-b may extend outward from the front door doorway (e.g., from front door frame 114 or front door frame rib 700 of the cabinet 100) to block the front door 102 from being completely or fully closed and/or sealed. Therefore, the amount of extension by the front ends 304a-b of rods 300a-b may be approximately the amount of extension needed to block the front door 102 from being able to close completely (e.g., the front door 102 positioned in an ajar state or a further open state). For example, the front ends 304a-b of the rods 300a-b may extend outward past the front door frame 114, front door frame rib 700, or front door doorway of the cabinet 100 by approximately one inch (e.g., 2.55 cm).

It should be understood that the cabinet 100 may include any number of rods 300 (e.g., with respective first biasing elements 310 and bias brackets 500). For example, one or more rear cam locks 200 on the rear door 104 may be associated with a respective one or more rods 300, first biasing elements 310 and bias brackets 500. The cabinet 100 may also include one or more rear cam locks 200 not associated with a respective one or more rods 300, first biasing elements 310, and bias brackets 500. The positioning of the rods 300, first biasing elements 310 and bias brackets 500 may also depend on the position of the respective rear cam lock 200. For example, if the rear cam lock 200 is located near the top of the rear door 104, then the respective rod 300, first biasing element 310 and/or bias bracket 500 may also be similarly positioned so that the operation of the rear cam lock 200 is associated with the ability of the front door 102 to be closed or not to be closed, as described herein. Therefore, the above description should not be interpreted as a limitation of the present disclosure, but merely an illustration.

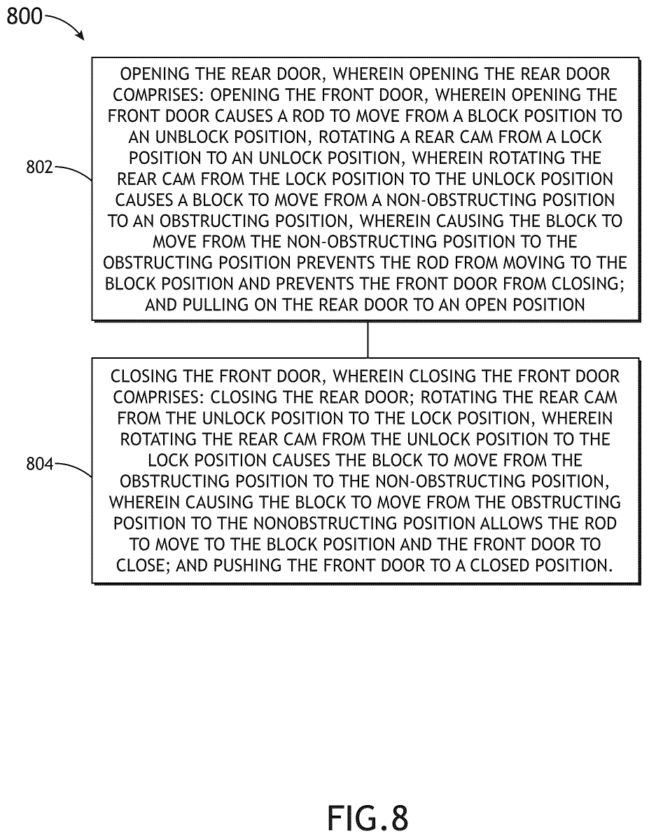

FIG. 8 illustrates a process flow diagram depicting a method 800 for operating the rear door 104 and the front door 102 of the cabinet 100 when the front door 102 and the rear door 104 are initially closed, in accordance with one or more embodiments of the disclosure. The method 800 may be utilized in the operating of the cabinet 100 of the current disclosure, such as a cabinet 100 for storing batteries and/or power equipment in an outdoor enclosure.

In embodiments, the method 800 includes a step 802 of opening the rear door 104, wherein opening the rear door 104 includes: opening the front door 102, wherein opening the front door 102 causes a rod 300 to move from a block position to an unblock position; rotating a rear cam 202 from a lock position to an unlock position, wherein rotating the rear cam 202 from the lock position to the unlock position causes a block 501 to move from a non-obstruct position 600 to an obstruct position 601, and wherein causing the block 501 to move from the non-obstruct position 600 to the obstruct position 601 prevents the rod 300 from moving to the block position and prevents the front door 102 from closing; and pulling on the rear door 104 to an open position. For example, when the front door 102 is opened, the first biasing element 310 biases the rear end 305 of the rod 300 to the unblock position, allowing the rear cam 202 to rotate to the unlock position, and causing the front end 304 of the rod 300 to extend outward to an extended position. Also, when the rear cam lock 200 is unlocked and the rear cam 202 is rotated from the lock to unlock position, the second biasing element 502 moves the block 501 from the un-obstruct position 600 to the obstruct position 601, which prevents the rod 300 from reversing back to the block position, and retains the front end 304 of the rod 300 in the extended position, preventing the front door 102 from completely closing.

In embodiments, the method includes a step 804 of closing the front door 102, wherein closing the front door 102 includes closing the rear door 104; rotating the rear cam 202 from the unlock position to the lock position, wherein rotating the rear cam 202 from the unlock position to the lock position causes the block 501 to move from the obstruct position 601 to the non-obstruct position 600, and wherein causing the block 501 to move from the obstruct position 601 to the non-obstruct position 600 allows the rod 300 to move to the block position and the front door 102 to close; and pushing the front door 102 to a closed position (e.g., a fully closed position). For example, by closing the rear door 104 and locking the rear cam lock 200, the rear cam 202 is moved from the unlock position to the lock position, which in turn biases the block 501 from the obstructive position to the non-obstructive position where the face 504 of the block 501 no longer obstructs the rear end 305 of the rod 300 from passing through the aperture 506 of the rod guide 402 to the block position. Moving the rear end 305 of the rod 300 to the block position also causes the front end 304 of the rod 300 to retract from the extended position, allowing the front door 102 to be fully closed.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed is:

1. A cabinet comprising:
a cabinet frame;
a front door coupled to a front side of the cabinet frame;
a rear door coupled to a rear side of the cabinet frame comprising a rear cam disposed on an internal side of a rear door, wherein the rear cam is configured to rotate between a lock position and an unlock position, wherein the rear cam couples the rear door to the rear side of the cabinet frame, in the lock position;
a rod positioned orthogonal to the front door and to the rear door, wherein in a closed configuration of the front door, the front door contacts a front end of the rod and biases a rear end of the rod toward the rear door from an unblock position to a block position, wherein the biasing of the rod from the unblock position to the block position prevents a rotation of the rear cam from the lock position to the unlock position; and
a first biasing element configured to bias the rod from the block position to the unblock position upon an opening of the front door, wherein biasing the rod from the block position to the unblock position allows the rear cam to move from the lock position to the unlock position.

2. The cabinet of claim 1, further comprising a bias bracket, the bias bracket comprising:
a block; and
a second biasing element mechanically coupled to the block, the second biasing element configured to bias the block against the rear cam, whereupon a movement of the rear cam from the lock to the unlock position, the block is configured to translate from a non-obstruct position to an obstruct position, whereupon the translation of the block from the non-obstruct position to the obstruct position causes the rod to be blocked from biasing from the unblock position to the block position, wherein when the rod is the block position a front end of the rod extends outward to an extended position, a resulting extension of the front end of the rod in the extended position blocks the front door and prevents the front door from fully closing.

3. The cabinet of claim 2, wherein the rear door cannot be opened unless the front door has been opened.

4. The cabinet of claim 3, wherein the rear door cannot be opened unless the rod is biased to the unblock position and the rear cam has rotated from the lock position to the unlock position.

5. The cabinet of claim 4, wherein the front door cannot be closed unless the rear door has been closed and the rear cam has rotated from the unlock position to the lock position.

6. The cabinet of claim 5, further comprising a front cam latch comprising a front cam disposed on an internal side of the front door, wherein the front cam is configured to couple the front door to the front side of the cabinet frame.

7. The cabinet of claim 1, further comprising a rod guide comprising an aperture configured to receive the rod via the aperture and guide the rod toward a face of the block.

8. The cabinet of claim 1, wherein the cabinet is configured to store electronic equipment.

9. A system comprising:
a cabinet comprising:
a cabinet frame;
a front door coupled to a front side of the cabinet frame comprising:
a rear door coupled to a rear side of the cabinet frame comprising:
a rear cam base accessible from an external side of the rear door; and
a rear cam disposed on an internal side of the rear door and mechanically coupled to the rear cam base, wherein the rear cam is configured to rotate between a lock position and unlock position, wherein the rear cam couples the rear door to the rear side of the cabinet frame in the lock position;
a rod mechanically coupled to at least one of the cabinet frame or a cabinet panel and positioned orthogonal to the front door and to the rear door, wherein a closed configuration of the front door contacts a front end of the rod and biases a rear end of the rod toward the rear door from an unblock position to a block position, wherein the biasing of the rod from the unblock position to the block position prevents a rotation of the rear cam from the lock position to the unlock position;
a first biasing element configured to bias the rod from the block position to the unblock position upon an opening of the front door, wherein biasing the rod from the block position to the unblock position allows the rear cam to move from the lock position to the unlock position; and
a bias bracket comprising:
a block; and
a second biasing element coupled to the block, the second biasing element configured to bias the block against the rear cam, whereupon a movement of the rear cam from the lock to the unlock position causes the block to translate from a non-obstruct position to an obstruct position via the second biasing element, whereupon the translation of the block from the non-obstruct position to the obstruct position causes the rod to be blocked from biasing from the unblock position to the block position, wherein when the rod is the block position a front end of the rod extends outward to an extended position, wherein a resulting extension of the front end of the rod in the extended position blocks the front door and prevents the front door from fully closing.

10. The system of claim 9, wherein the rear door cannot be opened unless the front door has been opened.

11. The system of claim 10, wherein the rear door cannot be opened unless the rod is biased to the unblock position and the rear cam has rotated from the lock position to the unlock position.

12. The system of claim 11, wherein the front door cannot be closed unless the rear door has been closed and the rear cam has rotated from the unlock position to the lock position.

13. The system of claim 12, the front door further comprising a front cam latch comprising:
a front cam base accessible from an external side of the front door; and
a front cam disposed on an internal side of the front door and mechanically coupled to the front cam base, wherein the front cam is configured to couple the front door to the front side of the cabinet frame.

14. The system of claim 9, further comprising a rod guide comprising an aperture configured to receive the rod via the aperture and guide the rod toward a face of the block.

15. The system of claim 9, wherein the cabinet is configured to store electronic equipment.

16. A method for operating a rear door and a front door of a cabinet, when the rear door and the front door are each initially closed, the method comprising:
opening the rear door, wherein opening the rear door comprises:
opening the front door, wherein opening the front door causes a rod to move from a block position to an unblock position;
rotating a rear cam from a lock position to an unlock position, wherein rotating the rear cam from the lock position to the unlock position causes a block to move from a non-obstruct position to an obstruct position, wherein causing the block to move from the non-obstruct position to the obstruct position prevents the rod from moving to the block position and prevents the front door from fully closing; and
pulling on the rear door to an open position.

17. The method of claim 16, further comprising:
closing the front door, wherein closing the front door comprises:
closing the rear door;
rotating the rear cam from the unlock position to the lock position, wherein rotating the rear cam from the unlock position to the lock position causes the block to move from the obstruct position to the non-obstruct position, wherein causing the block to move from the obstruct position to the non-obstruct position allows the rod to move to the block position and the front door to close; and
pushing the front door to a fully closed position.

18. The method of claim 17, wherein the rear door cannot be opened unless the front door has been opened.

19. The method of claim 18, wherein the rear door cannot be opened unless the rod is biased to the unblock position and the rear cam has rotated from the lock position to the unlock position.

20. The method of claim 19, wherein the front door cannot be closed unless the rear door has been closed and the rear cam has rotated from the unlock position to the lock position.
